(19) United States
(12) Patent Application Publication
(10) Pub. No.: US 2018/0329007 A1
(43) Pub. Date: Nov. 15, 2018

(54) PHASE CYCLED MAGNETIC RESONANCE SPECTROSCOPE IMAGING

(71) Applicant: ST. JUDE CHILDREN'S RESEARCH HOSPITAL, MEMPHIS, TN (US)

(72) Inventors: Junyu Guo, Memphis, TN (US); Wilburn E. Reddick, Bartlett, TN (US)

(21) Appl. No.: 15/774,839

(22) PCT Filed: Nov. 9, 2016
(86) PCT No.: PCT/US16/61066

§ 371 Date: May 9, 2018

Related U.S. Application Data
(60) Provisional application No. 62/252,699, filed on Nov. 9, 2015.

(51) Int. Cl. G01R 33/485; G01R 33/46

(52) U.S. Cl. CPC G01R 33/485; G01R 33/4616

(57) ABSTRACT

Systems, methods, and other embodiments associated with phase cycled magnetic resonance spectroscopic imaging (PCSI). According to one embodiment, a method includes applying an excitation radio frequency (RF) pulse having a low flip angle to a sample. The method further includes adjusting the phase of the RF to sweep through a frequency range based, at least in part, on PCSI. Sampling is then performed in the frequency range. The method also includes receiving a set of data based, at least in part, on the sampling in the frequency range.

### CROSS-REFERENCE TO RELATED APPLICATIONS

This Application claims the benefit of U.S. Provisional Patent Application No. 62/252,699 filed Nov. 9, 2015, which is hereby incorporated by reference in its entirety.

### BACKGROUND

Magnetic resonance spectroscopy (MRS) is a technique to study the physical, chemical, and biological properties of matter on the molecular scale. For example, MRS can noninvasively detect subtle biochemical changes in human tissue to provide molecular-level information of metabolism. Since spectroscopic measurements are typically taken in either the frequency domain or time domain, spectroscopic techniques can be divided into the frequency-resolved and the time-resolved methods.

### BRIEF DESCRIPTION OF THE DRAWINGS

The accompanying drawings, which are incorporated in and constitute a part of the specification, illustrate various systems, methods, and other embodiments of the disclosure. Illustrated element boundaries (e.g., boxes, groups of boxes, or other shapes) in the figures represent one example of the boundaries. In some examples one element may be designed as multiple elements or multiple elements may be designed as one element. In some examples, an element shown as an internal component of another element may be implemented as an external component and vice versa.

FIG. 1 illustrates one embodiment of a method associated with phase cycled magnetic resonance spectroscopic imaging.

FIG. 2A illustrates one embodiment of a scheme diagram of RF sequence associated with phase cycled magnetic resonance spectroscopic imaging.

FIG. 2B illustrates one embodiment of a precession diagram for an isochromat associated with phase cycled magnetic resonance spectroscopic imaging.

FIG. 3 illustrates another embodiment of magnitude profiles for four flip angles associated with phase cycled magnetic resonance spectroscopic imaging.

FIG. 4A illustrates one embodiment of magnetization profiles associated with phase cycled magnetic resonance spectroscopic imaging.

FIG. 4B illustrates one embodiment of phase profiles associated with phase cycled magnetic resonance spectroscopic imaging.

FIG. 5A illustrates one embodiment of magnetization real components and phase shifting increases without overall magnetization phase correction for the cycled RF phase.

FIG. 5B illustrates one embodiment of magnetization real components and phase shifting increases with overall magnetization phase correction.

FIG. 6A illustrates one embodiment of an acquisition window selection associated with phase cycled magnetic resonance spectroscopic imaging.

FIG. 6B illustrates example responses functions for the periods illustrated in FIG. 6A.

FIG. 7A illustrates one example of a conventional free induction decay graph.

FIG. 7B illustrates one embodiment of a spectrum associated with phase cycled magnetic resonance spectroscopic imaging.

FIG. 8A illustrates one embodiment of assumed metabolite signals associated with simulated spectrum according to phase cycled magnetic resonance spectroscopic imaging.

FIG. 8B illustrates one embodiment of simulated real signal associated with simulated spectrum according to phase cycled magnetic resonance spectroscopic imaging.

FIG. 8C illustrates another embodiment of simulated real signal associated with simulated spectrum according to phase cycled magnetic resonance spectroscopic imaging.

FIG. 8D illustrates another embodiment of simulated real signal associated with simulated spectrum according to phase cycled magnetic resonance spectroscopic imaging.

FIG. 9 illustrates an example graph of sample density associated with non-uniform phase cycled magnetic resonance spectroscopic imaging.

FIG. 10 illustrates one embodiment of a signal processing method associated with phase cycled magnetic resonance spectroscopic imaging.

FIG. 11 illustrates an example MR apparatus configured to perform phase cycled magnetic resonance spectroscopic imaging.

FIG. 12A illustrates one example of a spectral signal from the central region of phantom associated with phase cycled magnetic resonance spectroscopic imaging.

FIG. 12B illustrates the corresponding fitted spectrum after baseline correction associated with phase cycled magnetic resonance spectroscopic imaging.

FIG. 12C illustrates one example of a spectrum in the central region of phantom associated with the time-resolved single voxel spectroscopy.

FIG. 13A illustrates one example of a spectrum from healthy volunteer associated with phase cycled magnetic resonance spectroscopic imaging.

FIG. 13B illustrates one example of a spectrum from healthy volunteer associated with the time-resolved single voxel spectroscopy.

FIG. 14 illustrates one example of metabolic parametric maps from two repeated measurements associated with phase cycled magnetic resonance spectroscopic imaging.

FIG. 15A illustrates an embodiment of PCSI signals as a function of flip angle for a fixed T1 and TR.

FIG. 15B illustrates one embodiment of PCSI signals as a function of flip angle for a fixed T2 and TR.

FIG. 15C illustrates one embodiment of PCSI signals as a function of flip angle for a fixed T1 and T2.

FIG. 16A illustrates one embodiment of a PCSI spectrum of one voxel from higher resolution data showing peaks corresponding to example metabolites.

FIG. 16B illustrates one embodiment of a PCSI spectrum of nine voxels from the same data showing peaks corresponding to example metabolites.

FIG. 17 illustrate an example PCSI spectrum corresponding to different flip angles for a phantom.

FIG. 18 illustrate an example fitted PCSI spectrum corresponding to different flip angles for a human volunteer.

FIG. 19 illustrate an example metabolic parameter maps having regions of identified lesions.

### DETAILED DESCRIPTION

Embodiments or examples illustrated in the drawings are disclosed below using specific language. It will nevertheless be understood that the embodiments or examples are not intended to be limiting. Any alterations and modifications in the disclosed embodiments and any further applications of the principles disclosed in this document are contemplated as would normally occur to one of ordinary skill in the pertinent art.

Magnetic resonance spectroscopy imaging (MRSI) can simultaneously acquire magnetic resonance (MR) data regarding both subtle changes in the chemical composition of a sample and anatomic spatial information regarding the sample. However, MRSI has not been widely accepted as a clinical tool because the MR data acquisition is very time consuming. For example, it may take more than thirty minutes to acquire an image with a 32×32 acquisition matrix using a Point Resolved Spectroscopy (PRESS) sequence. Furthermore, the strong water signal from traditional imaging techniques may overwhelm the tiny metabolite signal, which is generally 10,000 times weaker that the water signal. While outer volume suppression (OVS) may be used to prevent spectral contamination by peripheral lipid and water signals using spatial pre-saturation bands. However, the precise placement of the spatial pre-saturation bands is challenging, time consuming, and it requires special technician training and skills.

Described herein are examples of systems, methods, and other embodiments associated with phase cycled MR spectroscopic imaging (PCSI). The systems, methods, and other embodiments acquire data using frequency resolved techniques rather than time resolved techniques of conventional MRSI. The frequency resolved technique uses a radio frequency phase to sweep through a targeted frequency range in a spectrum, thereby reducing the acquisition time. The frequency range may be targeted based on a prior knowledge of the spectrum or a specifically targeted substance, such as a metabolite. More particularly, PCSI adjusts the phase of the RF to sweep through the desired frequency range. The sweep may target a specific metabolite having signal peaks at frequencies corresponding to the target metabolite. Therefore, the sweep may be non-continuous to focus on the frequencies associated with the target metabolite. This is simpler than changing the magnetic field strength or the RF frequency as is typically done. The phase-sweep method of PCSI allows flexibility for non-uniform frequency sampling, which speeds up the acquisition. For example, the sweep rate may be less than 100 milliseconds (ms) per image.

PCSI may be implemented with an ultra-low flip angle to generate a sharp response function and achieve high spectral resolution with very low specific absorption rate (SAR). The flip angle, also called tip angle, is the amount of rotation the net magnetization (M) experiences during application of an RF pulse. In some embodiments, the RF pulses have an ultra-low flip angle, for example, a flip angle of less than 1°. Additionally, the PCSI method simplifies scanning by making spatial suppression unnecessary. Accordingly, the described systems, methods, and embodiments make MR data acquisition more efficient and flexible to facilitate faster spatial encoding and non-uniform sampling in the frequency domain.

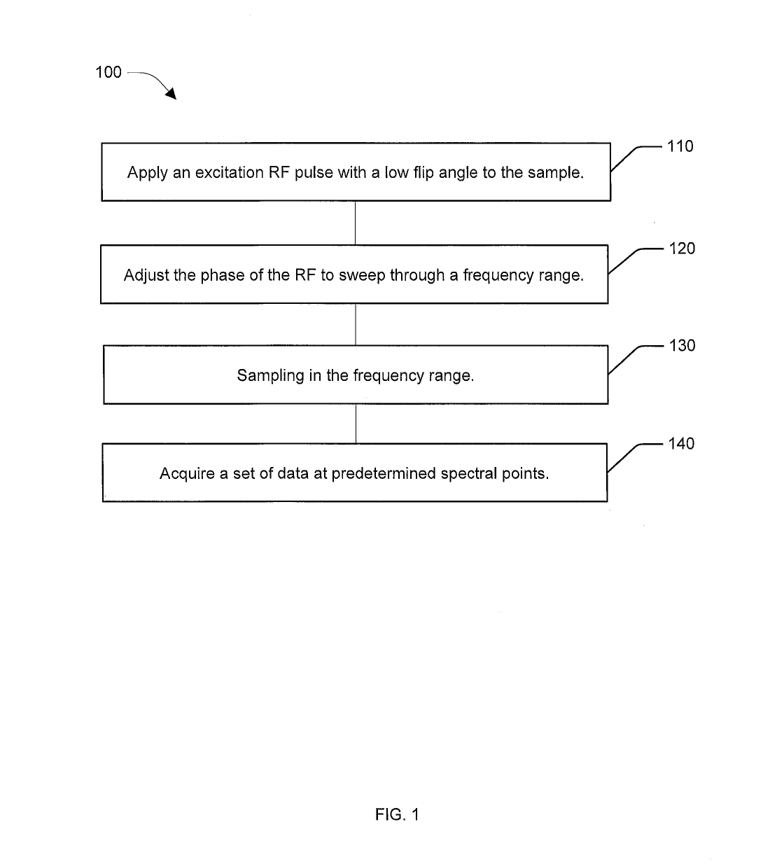

FIG. 1 illustrates one embodiment of a method associated with phase cycled magnetic resonance spectroscopic imaging. The method 100 may operate in conjunction with an MR system. For example, PCSI may be used as a tool in clinical settings for noninvasively obtaining spatial and metabolic information from a sample on a molecular level. Thus, metabolic mapping can be provided. For example, PCSI may be used to detect J-coupled metabolites in humans.

At 110, an excitation radio frequency (RF) pulses having a low flip angle is applied to a sample. The RF pulses deliver energy to the nuclei in the sample, which puts the nuclei into a higher energy state. By producing a net transverse magnetization the MR system can observe a response from the excited system. The sample may be biological tissue, such as a human brain tissue.

In one embodiment, the RF pulses may be a portion of a pulse sequence. The pulse sequence may include more excitation RF pulses or a preselected set of gradient pulses that are repeated during a scan of the sample rather than a continuous wave RF. The interval between pulses as well as the amplitude and shape of the pulses may be altered based, at least in part, on specific type of pulse sequence. For example, the pulse sequence may be balanced steady-state free precession (bSSFP) sequence.

Furthermore, the flip angle of the RF pulses is based, at least in part, on the pulse sequence. The low flip angle may be a flip angle of 5° or less. The flip angle is the angle to which the net magnetization is rotated or tipped relative to the main magnetic field direction via the application of an RF excitation pulse at the Larmor frequency. In some embodiments, the RF pulses have an ultra-low flip angle of approximately 1° or less. The flip angle is ultra-low to generate a sharp response function and achieve high spectral resolution.

At 120, the phase of the RF pulses is adjusted to sweep through a frequency range based, at least in part, on phase cycled spectroscopic imaging (PCSI). As the pulse sequence progresses, the phase of the RF pulses is cycled. For example, the bSSFP sequence may sweep through a plurality of phase cycles.

At 130, a frequency range may be uniformly or non-uniformly sampled as a result of the phase of the RF pulses being adjusted at 120. The sampling occurs at one or more frequencies in the frequency range. The phase may be cycled to specifically target the one or more frequencies. The sampling may be uniform and, for example, be sampled at frequencies separated by a predetermined interval. Alternatively, the sampling may be non-uniform at one or more predetermined target frequencies. The one or more frequencies may be selected based, at least in part, on specific substances that are trying to be identified in the sample. For example, if specific metabolites are being targeted, the frequencies corresponding to those metabolites may be targeted. By sweeping through a frequency range at specific frequencies, substances that emit at those frequencies are more easily identified. Thus, target frequencies may be selected from the frequency range based, at least in part, on a target metabolite; and then sampling may be performed at the target frequencies.

At 140, MR data is acquired at the frequencies in the frequency range from the sweep. Thus, the MR data is acquired in the k- and frequency-space (i.e., k-f-space), unlike conventional MRS imaging which acquires the MR data in the k-t-space. In some embodiments the MR data is acquired in the k-frequency-time space.

In one embodiment, the data set may be graphed to illustrate spectral peaks that may correspond to frequencies associated with the targeted metabolites. Alternatively, the MR data set may be used to generate images of the sample. In one embodiment, the MR data is used to generate the images of the sample may illustrate and differentiate between varying levels of metabolites in the sample. For example, the images may be parametric maps of the sample. As discussed above, the MR data acquisition is sped up by non-uniformly sampling in the frequency range because specific frequencies may be targeted.

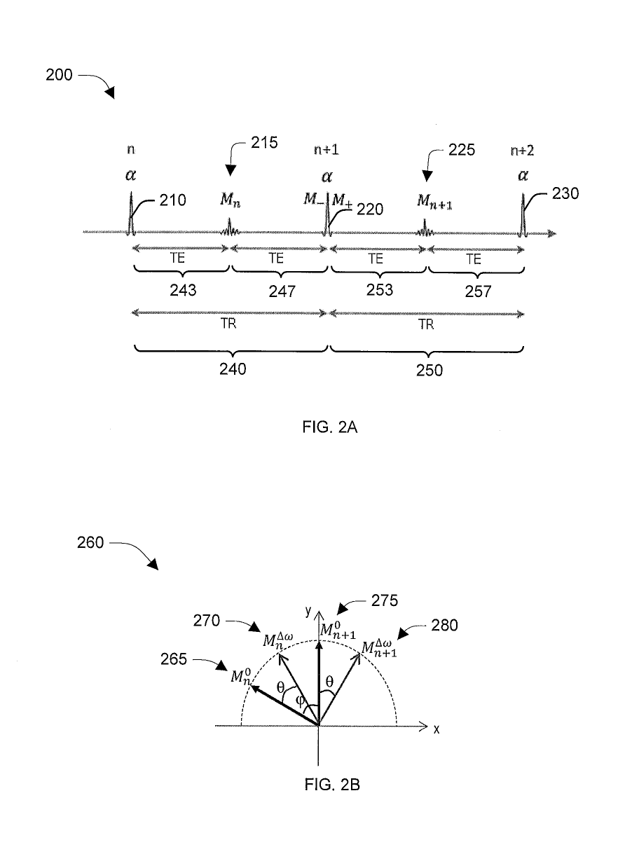

FIG. 2A illustrates one embodiment of a scheme diagram 200 of a bSSFP pulse sequence associated with phase cycled magnetic resonance spectroscopic imaging. As discussed above, the pulses having an ultra-low flip angle (See e.g., act 110 of FIG. 1) and cycled phase (See e.g., act 120 of FIG. 1) may be based, at least in part, on a bSSFP pulse sequence. The scheme diagram 200 illustrates pulses 210, 220, and 230 of a bSSFP pulse sequence. The pulses 210, 220, and 230 are each associated with an ultra-low flip angle, α and a specific phase, φₙ.

Steady-state magnetization peaks 215 and 225 of a magnetization profile result from a series of pulses like 210 and 220. In particular, the magnetization profile associated with a specific cycled RF phase results in at least one sharp response peak at the at least one frequency corresponding to the presence of a substance, such as a metabolite, in the sample.

The scheme diagram 200 also illustrates two repetition time (TR) periods 240 and 250. The TR periods 240 and 250 may be selected based, at least in part, on a desired response peak. For example, the average chemical shift between body fat and water is approximately 3.35 ppm corresponding to a chemical shift on 3T scanner of about 413 Hz. Therefore, TR period of 2.4 ms may be selected for TR periods 240 and 250 so that the period of the response function is 417 Hz, and thus closer to the water-fat shift 413 Hz.

The scheme diagram 200 also illustrates four time echo (TE) periods 243, 247, 253, and 257. The TE periods represent the time in milliseconds between the application of the RF pulses 210 and 220 and the magnetization peaks 215 and 225 of the magnetization profile after the RF pulses 210 and 220. For example, TE period 243 is the TE period before the magnetization profile 215, and TE period 247 is the TE period subsequent to the magnetization profile 215. The TE period may be based, at least in part, on TR. The value of TE may be changed to change the pulse sequence to, for example, Fast Imaging with Steady-State Precession (FISP) or time reversed FISP, referred to as, PSIF instead of bSSFP. The length of the TE period can also be selected based, at least in part, on desired T1 and/or T2 contrast.

Thus, the bSSFP pulse sequence represented by the scheme diagram 200 includes a number of parameters, such as flip angle, α, TR, and TE that are selected by virtue of the derivation of the pulse sequence. An example derivation of a bSSFP pulse sequence is detailed below.

In one embodiment, matrix representation is used to derive the steady state magnetization of bSSFP. Since nuclear magnetization precession is clockwise, rotational matrices with an angle α are defined as follows:

$${R}_{x}^{-} ( α ) = [ \begin{matrix}1 & 0 & 0 \\ 0 & cos α & sin α \\ 0 & - sin α & cos α\end{matrix} ] , \\ {R}_{y}^{-} ( α ) = [ \begin{matrix}cos α & 0 & - sin α \\ 0 & 1 & 0 \\ sin α & 0 & cos α\end{matrix} ] , \\ {R}_{z}^{-} ( α ) = [ \begin{matrix}cos α & sin α & 0 \\ - sin α & cos α & 0 \\ 0 & 0 & 1\end{matrix} ] \qquad ( 1 )$$

A component with off-resonance frequency of Δf=2πΔω, the precession angle at time of echo (TE) is θ=2π·Δf·TE. For example, FIG. 2B illustrates a precession diagram 260 from Mₙ to Mₙ₊ for an isochromat with off resonance frequency of 0 and Δω. The isochromat represents a microscopic group of spins, which resonate at the same frequency. The spin precesses around a circle in the xy-plane and the net magnetization is the length, amplitude or magnitude of the magnetization vector. This quantity is normally represented on a pixel-by-pixel basis in a MR image, and thus corresponds to the amplitude or magnitude image, having magnetization profiles for Mₙ⁰ 265, Mₙ^{Δω} 270, Mₙ₊₁⁰ 275, Mₙ₊₁^{Δω} 280. The magnetization, Mₙ₊₁^{Δω} 280, at (n+1)^{th} echo is calculated from the magnetization, M₊, just after the (n+1)^{th} RF pulse 220 (as shown in FIG. 2A).

$$\begin{matrix} {M}_{n + 1}^{Δω} = {E}_{A} {R}_{Z}^{-} ( θ ) {M}_{+} + {E}_{B} & ( 2 ) \\ {E}_{A} = [ \begin{matrix}{e}_{2} & 0 & 0 \\ 0 & {e}_{2} & 0 \\ 0 & 0 & {e}_{1}\end{matrix} ] , {E}_{B} = ( 1 - {e}_{1} ) {M}_{0} = [ \begin{matrix}0 \\ 0 \\ 1 - {e}_{1}\end{matrix} ] , {e}_{1} = {e}^{- \frac{TE}{{T}_{1}}} , {e}_{2} = {e}^{- \frac{TE}{{T}_{2}}} , {M}_{0} = [ \begin{matrix}0 \\ 0 \\ 1\end{matrix} ] & ( 3 )\end{matrix}$$

Where T₁ is the spin-lattice relaxation time, and T₂ is the spin-spin relaxation time. The matrices E_{A} and E_{B} represent the relaxation process. The matrix R_{z}⁻(θ) represents a precession process of an off-resonance component with Δω during TE. By using equation (2), magnetization evolution from Mₙ^{Δω} 270 to Mₙ₊₁^{Δω} 280 becomes as follows:

M₋=E_{A}R_{Z}⁻(θ)Mₙ^{Δω}+E_{B},

M₊=Rₓ⁻(αₙ₊₁)M₋,

Mₙ₊₁^{Δω}=E_{A}R_{Z}⁻(θ)M₊+E_{B} (4)

To simplify the form in equation (4), the rotation axis of (n+1)^{th} RF pulse is selected as X axis, and so the second equation in equation (4) is simplified without the term of the cycled RF phase φ.

The cycled RF phase is included in Mₙ, which will be included in the following steady state equation. When reaching the steady state, the relationship between Mₙ^{Δω} 270 to Mₙ₊₁^{Δω} 280 is as follows:

Mₙ₊₁^{Δω}=R_{Z}⁻(φ)Mₙ^{Δω} (5)
where φ is the RF phase change from the n^{th} RF to (n+1)^{th} RF pulse. φ is a constant for each measurement (or each image). By solving equations (4) and (5), the steady-state magnetization is given by:

$${M}_{n}^{Δω} = \frac{{E}_{A} {R}_{Z}^{-} ( θ ) {R}_{x}^{-} ( {α}_{n + 1} ) {E}_{B} + {E}_{B}}{{R}_{Z}^{-} ( ϕ ) - {E}_{A} {R}_{Z}^{-} ( θ ) {R}_{x}^{-} ( {α}_{n + 1} ) {E}_{A} {R}_{Z}^{-} ( θ )} \qquad ( 6 )$$

The complex form of the transverse magnetization in equation (6) becomes:

$${M}_{xy}^{Δω} = \frac{{e}_{2} ( 1 - {e}_{1}^{2} ) ( {e}_{2}^{2} {e}^{- i θ} - {e}^{- i ( ϕ - θ )} ) sin α}{\begin{matrix}{e}_{2}^{2} cos ( ϕ - 2 θ ) ( 1 + cos α ) ( 1 - {e}_{1}^{2} ) + \\ ( {e}_{1}^{2} - {e}_{2}^{4} ) cos α + {e}_{1}^{2} {e}_{2}^{4} - 1\end{matrix}} \qquad ( 7 )$$

The magnitude of the transverse magnetization becomes:

$$\vert {M}_{xy}^{Δω} \vert = \frac{{e}_{2} ( 1 - {e}_{1}^{2} ) sin α \sqrt{{e}_{2}^{4} - 2 {e}_{2}^{2} cos ( ϕ - 2 θ ) + 1}}{\begin{matrix}1 - {e}_{2}^{2} cos ( ϕ - 2 θ ) ( 1 + cos α ) ( 1 - {e}_{1}^{2} ) - \\ ( {e}_{1}^{2} - {e}_{2}^{4} ) cos α - {e}_{1}^{2} {e}_{2}^{4}\end{matrix}} \qquad ( 8 )$$

For φ,θ=0, the equation (8) becomes:

$$\vert {M}_{xy}^{0} \vert = \frac{{e}_{2} ( 1 - {e}_{1}^{2} ) sin α}{1 - ( {e}_{1}^{2} + {e}_{2}^{2} ) cos α + {e}_{1}^{2} {e}_{2}^{2}} \qquad ( 9 )$$

For φ=π, θ=0 used in most of bSSFP sequences, the equation (8) becomes:

$$\vert {M}_{xy}^{0} \vert = \frac{{e}_{2} ( 1 - {e}_{1}^{2} ) sin α}{1 - ( {e}_{1}^{2} - {e}_{2}^{2} ) cos α - {e}_{1}^{2} {e}_{2}^{2}} \qquad ( 10 )$$

In equation (8) with φ=0, the transverse magnetization is a periodic function of the precession angle θ, which corresponds to an off-resonance frequency. The period of this function is 2θ_{T}=2π, which corresponds to an off-resonance frequency range of Δf_{T}=1/TR. In one embodiment, the magnitude profile of the transverse magnetization were computed for different flip angles, such as 0.5°, 1°, 10°, 30°, using TR=5 ms, T₁=1300 ms, T₂=250 ms, which were chosen based, at least in part, on reported values for three targeted metabolites on 3T scanner. This embodiment of a bFFSP equation is one example of a pulse sequence that can be used in conjunction with PCSI. Alternatively, other pulse sequences may be used.

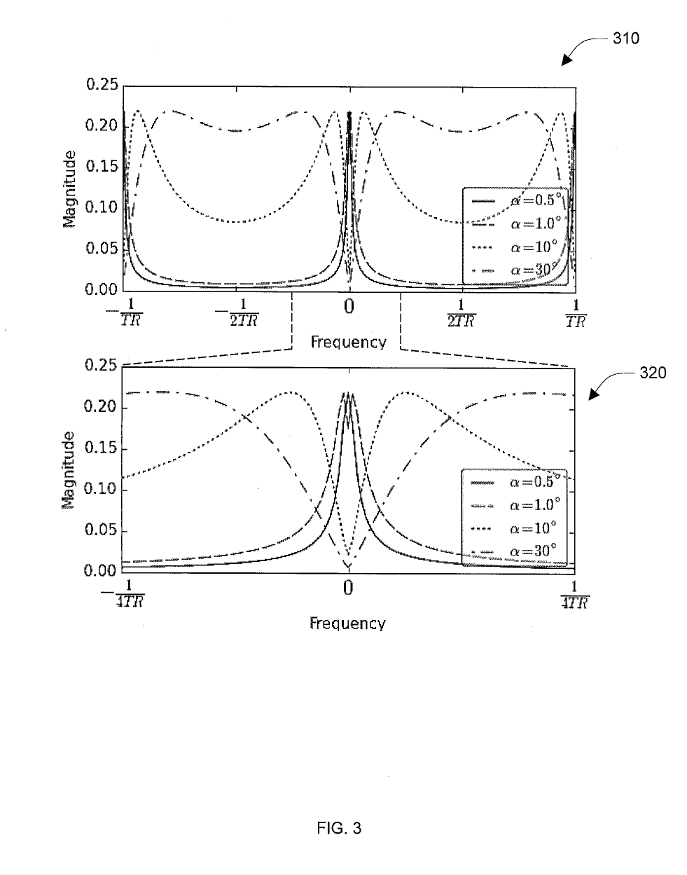

FIG. 3 shows magnitude profiles of magnetization for different flip angles computed using equation (7). Graph 310 shows the magnitude profiles for 0.5°, 1°, 10°, and 30°. In one embodiment, PCSI, using a bSSFP pulse sequence, is used large angle (e.g., 30°), the magnitude in a large range of frequency is close to the maximum, and the magnitude in a small range of frequency is close to zero, which leads to banding artifacts in bSSFP images. The shape of magnitude for a small angle is approximately opposite, in which only a small range of magnitude is large close to the maximum and the major range of magnitude is very small close to zero. Especially for an ultra-low flip angle (e.g., 0.5°), the profile had a sharp peak as shown in graph 320, which is a zoom-in of graph 310. Accordingly, PCSI may use a low flip angle.

The desired flip angle may be different than actual flip angle measured in the sample. For example, the desired flip angle may be 0.3, but to achieve a flip angle of 0.3 in the sample, a 0.7 flip angle may need to be applied to the sample. In this manner, the applied flip angle may be calibrated such that the desired flip angle is present in the sample in order to maximize the resulting signal.

Returning to the derivation of the steady-state magnetization of bSSFP, for spectroscopic imaging, signal to noise ratio (SNR) may have a large impact on the results. In one embodiment, to achieve a strong signal, an desired flip angle, α, is calculated for the maximum of the magnetization |M_{xy}⁰| for φ,θ=0 using equation (9). In simulations with T₁=1300 ms, T₂=250 ms, and TR=5 ms, the desired flip angle, α, and the maximum magnetization are 0.5° and 0.22, respectively.

For PCSI, the sweep rate is faster. In terms of images, a PCSI sweep rate may be approximately 13 images (or 76.8 ms per image), which is much more efficient than conventional frequency-sweeping methods having a sweep rate of approximately 1 Hz/s. In some embodiments, high sweep rates through the frequency range combined with the sampling being at non-continuous frequencies enable faster acquisitions. Due to the faster acquisition, multiple averages can be obtained in order to achieve in better SNR. Thus, after obtaining MR data for target frequencies, a spectrum for each voxel can be generated.

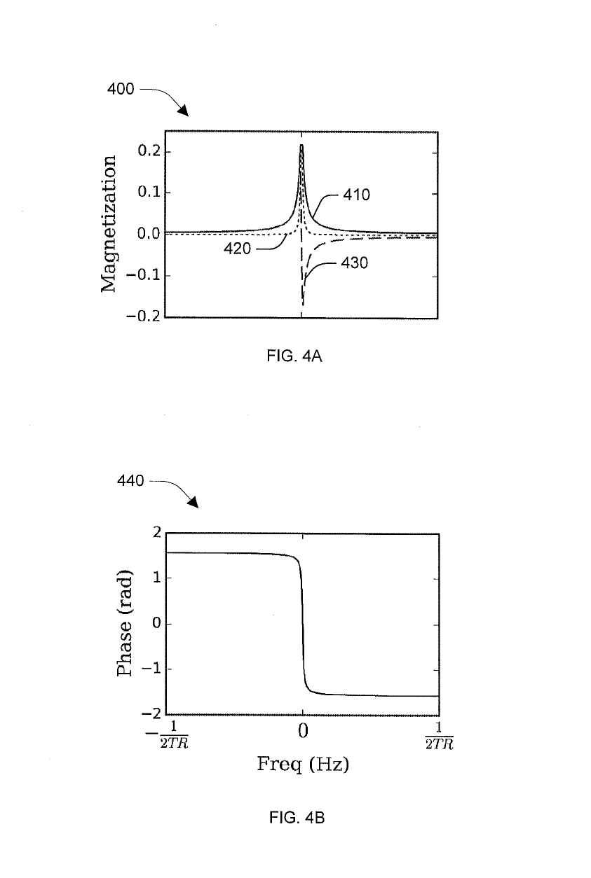

FIG. 4A illustrates one embodiment of magnetization profiles associated with phase cycled magnetic resonance spectroscopic imaging. Specifically, the graph 400 illustrates an absolute magnetization profile 410, a real magnetization profile 420, and imaginary magnetization profile 430 in one period. The absolute magnetization profile for α=0.5° has a sharp peak at Δf=0. The real magnetization profile 420 illustrates the real part of the magnetization, which represents an absorption component. The imaginary magnetization profile 430 illustrates the imaginary part, which represents a dispersion component.

FIG. 4B illustrates one embodiment of phase profiles associated with phase cycled magnetic resonance spectroscopic imaging. Specifically, the phase profile of graph 440 shows a sharp phase transition around Δf=0. This yields more information regarding the subtle change in the chemical composition of a sample. For example, if the sample is tumor tissue in a body, PCSI utilizing an ultra-low flip angle facilitates targeting the substances (e.g., metabolites, compounds, etc.).

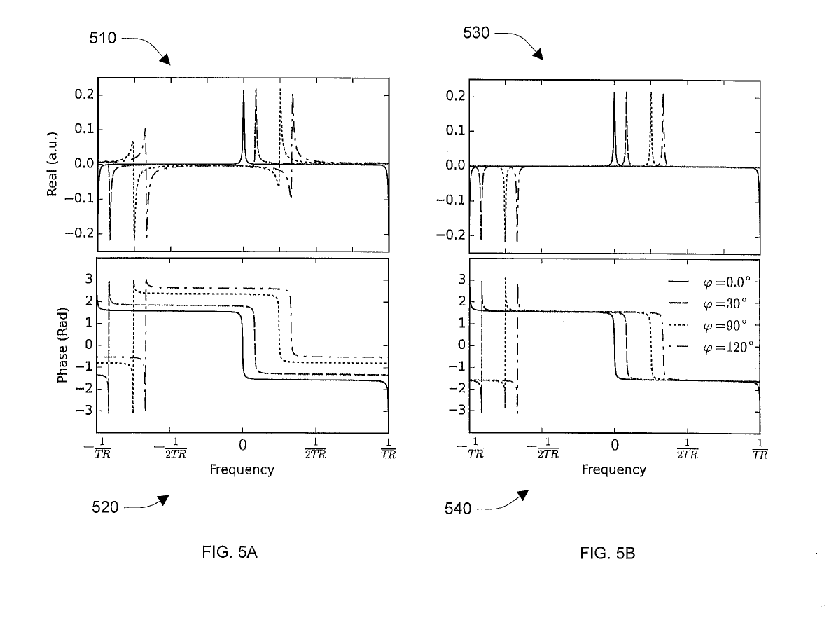

FIG. 5A illustrates one embodiment of magnetization real components 510 and phase shifting 520 as the cycled RF phase (φ) increases. The magnetization profiles of FIG. 5A are illustrated without the overall magnetization phase correction for the cycled RF phase. By changing the cycled RF phase φ for each image acquisition cycle, the real and phase profiles of magnetization are shifted as the phase as shown in FIG. 5A. However, the real component 510 is not a pure absorption component as the cycled RF phase is shifted away from zero. Besides shifting along the frequency direction, there is an additional overall phase shift of φ/2 relative to the phase profile of φ=0.

FIG. 5B illustrates one embodiment of magnetization absorption components 530 and phase shifting 540 as the cycled RF phase (φ) having magnetization profiles with the overall magnetization phase correction for the cycled RF phase. To make the real profiles pure absorption functions as it is at φ=0°. It requires that the phase profile shifts only along frequency direction without any additional phase shifting up and down. After correcting the overall phase shifting, the consistent real and phase profiles associated with absorption components 530. After correcting the overall phase shifting, the consistent phase profiles associated with the phase shifting 540, which could serve as good response functions for spectroscopic imaging.

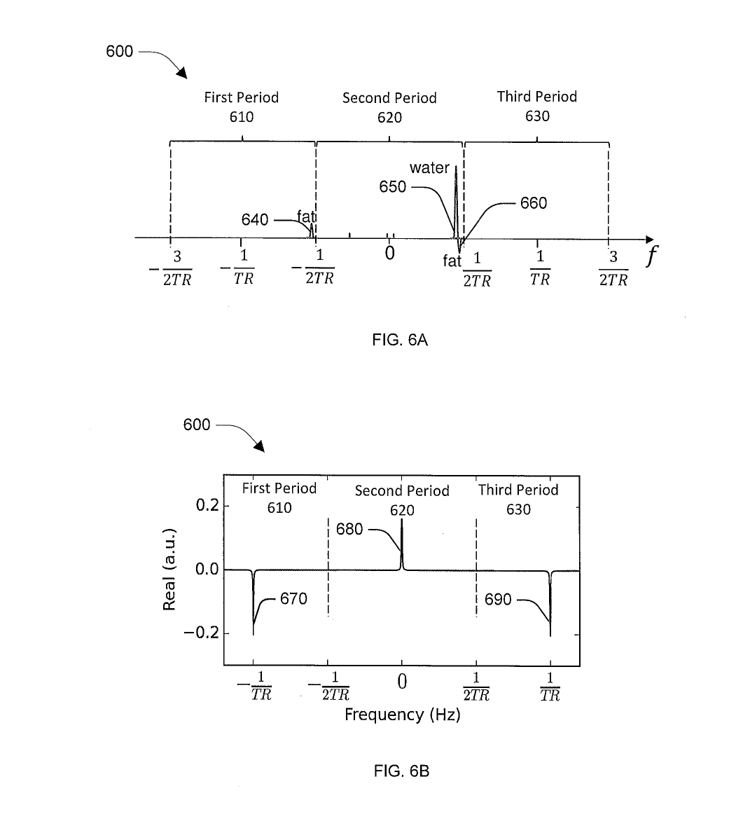

FIG. 6A illustrates one embodiment of acquisition window selection associated with phase cycled magnetic resonance spectroscopic imaging. In PCSI, water and fat suppression occur based, at least in part, on the sharp response function which suppresses the signal far from the selected frequency. Rather than water and fat signal suppression, in PCSI, appropriate values of protocol parameters, such as TR and flip angle α, are selected to achieve suppression in both water and fat. In one embodiment, the water and fat peaks are positioned close to one another using the periodic property of the response function to optimize the suppression of the fat and water signal. Water and fat signal suppression are described with respect to the acquisition window selection diagram 600.

The acquisition window selection diagram 600 of FIG. 6A includes a first period 610, a second period 620, and a third period 630. The first period 610 includes a fat peak 640 and the second period 620 includes a water peak 650. To suppress the water and fat signals, the fat peak 640 and the water peak 650 may be put into two consecutive frequency periods so that fat peak 640 can wrap around to the second period 620 as an inverted wrapped peak 660 close to water peak 650.

In one embodiment, the period length may be similar to the water-fat chemical shift for this configuration. For example, the average chemical shift between body fat and water is approximately 3.35 ppm. For example, the chemical shift on 3T scanner is about 413 Hz. Therefore, in this example, TR of 2.4 ms may be selected so that the period of the response function is 417 Hz the closest to water-fat shift 413 Hz. In one embodiment, second period 620 is selected for acquisition window because the metabolite and water peaks are in this period. Accordingly, the fat peak 640 of the first period 610 is wrapped to the second period 620 as the inverted wrapped peak 660. In this example, both the fat peak 640 and the water peak 650 are located at the end of the second period 620.

FIG. 6B illustrates one embodiment of example responses functions 670, 680, and 690 for the periods 610, 620, and 630, shown/in FIG. 6A. The response functions differ between the periods 610, 620, and 630. For example, the second period response function 680 is positive for the second period 620, and is negative for neighboring periods: the first period response function 670 and the third period response function 690. These differences in the response function inverts the fat peak 640 of the first period 610 to create the inverted wrapped peak 660 in the second period 620 shown in FIG. 6A. To make the targeted metabolite at the center of acquisition window, the system frequency may be decreased by a determined amount (e.g. 200 Hz) to shift the water peak to the end of the second period 620 in FIG. 6A. For example, for TR=2.4 ms, the desired flip angle α and the maximum amplitude of the magnetization is 0.24° and 0.22, respectively.

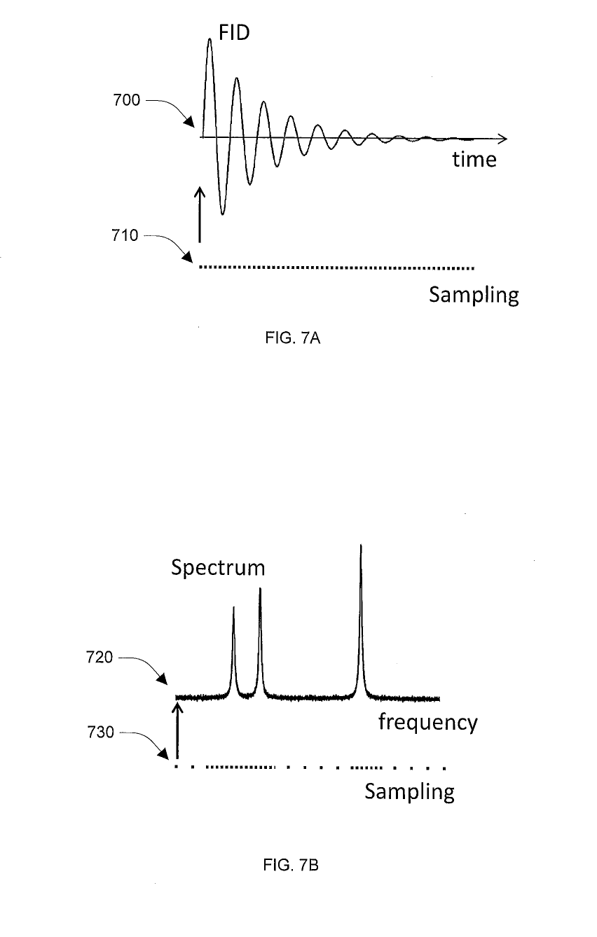

FIG. 7A illustrates one example of a conventional free induction decay 700 graph. In Fourier transform nuclear magnetic resonance spectroscopy, free induction decay (FID) is the observable NMR signal in time domain. Conventional uniform sampling in time domain 710 is associated with free induction decay 700.

FIG. 7B illustrates one embodiment of a spectrum 720 associated with phase cycled magnetic resonance spectroscopic imaging. The spectrum illustrates that frequencies associated with certain metabolites such as N-acetyl-asparate (NAA), creatine (Cr), and choline (Cho) can be specifically targeted. Accordingly, the frequency sampling 730 is non-uniform such that the frequency sampling is more densely targeted at those frequencies associated with the targeted substances. The phase-sweep method in PCSI allows flexibility non-uniform frequency sampling.

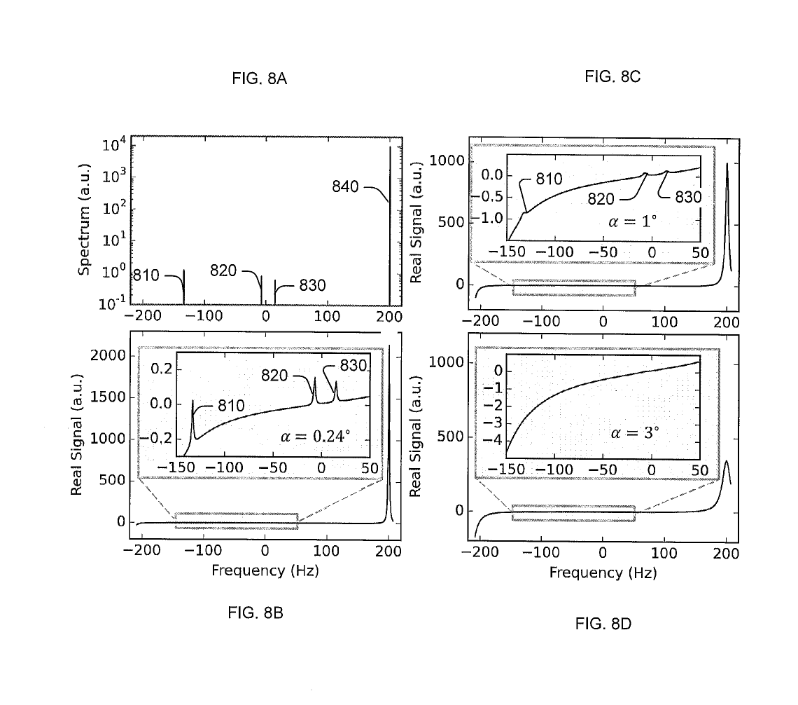

FIG. 8A illustrates one embodiment of assumed metabolite signals associated with simulated spectrum according to phase cycled magnetic resonance spectroscopic imaging. The assumed metabolite signals may be associated with specific frequencies.

For example, in one embodiment the signals associated are with N-acetyl-asparate (NAA) 810, creatine (Cr) 820, choline (Cho) 830, and water 840 in a logarithmic scale. The NAA 810, the Cr 820, Cho 830, and water 840 may be assumed to be delta functions with magnitudes of 1.2, 0.8, 0.6, and 1000 respectively. The sharpness of the response function may be based, at least in part, on the flip angle. In one embodiment, the metabolite signals are several orders lower than a water proton signal. Accordingly, by shifting water signal to 200 Hz, the assumed spectrum had all metabolite signals in one period as shown.

FIG. 8B illustrates one embodiment of simulated real signal associated with simulated spectrum having parameters of TR=2.4 ms, α=0.24°. A response function for each cycled RF phase φ from −180° to 180° with a step of 1° may be computed using equation (7). This computed spectrum is actually the convolution of the real response function discussed above with respect to FIG. 4A and the assumed spectrum discussed above with respect to FIG. 7B with resulting response functions for and resulting response functions for the NAA 810, the Cr 820, Cho 830, and water 840. The delta functions became the Lorentzian-like peaks in computed spectrum with α=0.24°.

FIG. 8C illustrates another embodiment of simulated real signal associated with a larger flip angle and resulting response functions for the NAA 810, the Cr 820, Cho 830, and water 840. Specifically, the stimulated real signal has parameter protocols with α=1°. For a larger flip angle α=1°, the peak heights decreased from FIG. 8B to FIG. 8C.

FIG. 8D illustrates a simulated real signal associated with simulated spectrum having an even larger flip angle. Specifically, the stimulated real signal has α=3°. The peaks became even smaller for a flip angle α=3° in FIG. 8D. Accordingly, a low flip angle or ultra-low flip angle generates a sharp response function and achieve high spectral resolution with very low specific absorption rate (SAR).

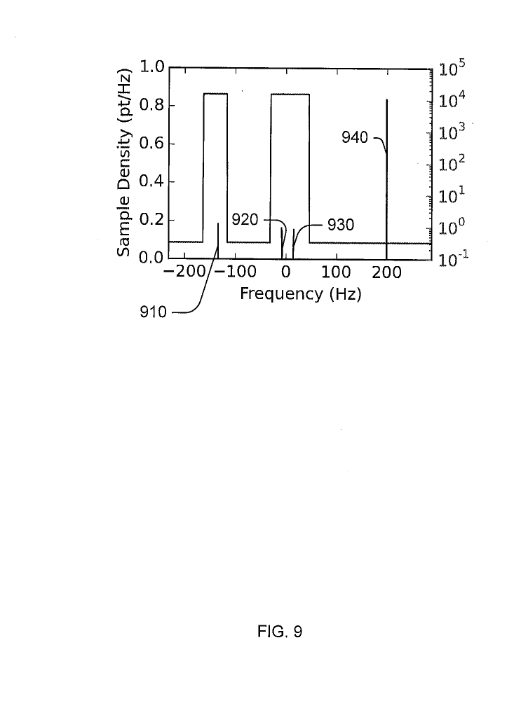

FIG. 9 illustrates an example graphical embodiment of sample density associated with non-uniform phase cycled magnetic resonance spectroscopic imaging. A higher sample density may be desired for targeted metabolites and a lower sample density may be desired at the other range of frequency. Suppose that the frequencies represent metabolites including NAA 910, Cr 920, Cho 930, and a water peak 940. The measurement of the metabolites may have a different cycled RF phase φ. For example, to uniformly sample the whole cycle of phase φ with a step of 1° or a corresponding period of frequency with a step of 1.16 Hz, 361 measurements can be taken which may take approximately 11 minutes with TR=2.4 ms, average number of 23, and 32 phase encoding. To further reduce the acquisition time, a non-uniform sample strategy can be used based, at least in part, on the prior knowledge of the brain spectrum.

Suppose the positions of three targeted metabolites in the spectrum are known as NAA 910 near −133 Hz, Cr 920 near −7 Hz, and Cho 930 near 15 Hz with the water peak 940 at 200 Hz on 3T scanner. In this embodiment, the sample range of the cycled RF phase is chosen from −200° to 250° instead of one exact period −180° to 180°. The dense sampling windows may be selected in ranges (−142°, −100°) and (−27°, 40°) with a step of 1° to cover the targeted spectrum, and the step in other ranges is selected as 10°. By selecting dense sample windows in specific ranges, the measurements can be reduced thereby reducing the total acquisition time. For example, in the described embodiment, the measurements number is reduced to 143 with a total acquisition time to 4:28 minutes. More advanced non-uniform sampling scheme may reduce the total acquisition time even further.

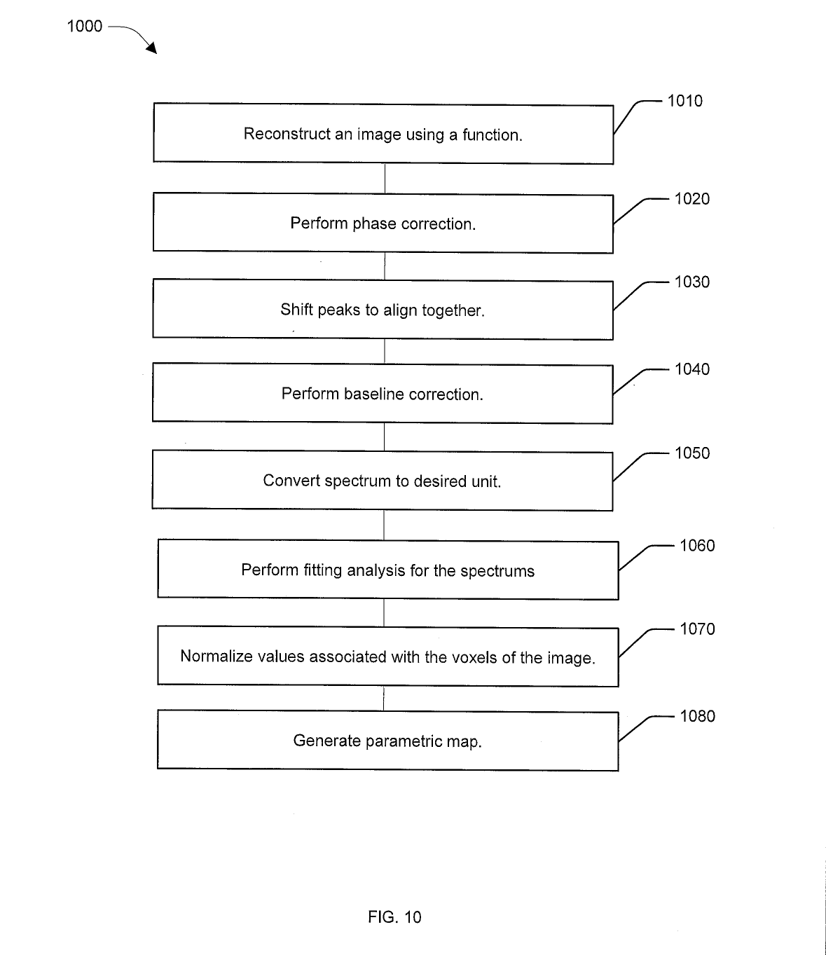

FIG. 10 illustrates one embodiment of a signal processing method regarding data measurements associated with phase cycled magnetic resonance spectroscopic imaging. Received measurement data in k-space may be saved on a scanner and transferred to workstation. At 1010, an image, including a plurality of voxels, is first reconstructed using a function, such as a fast Fourier transform, for each channel of the head coil. At 1020, the phase correction based, at least in part, on water peak is performed for each voxel to convert the real part of each complex profile to a pure absorption shape, which ensures that all phases are consistent for each voxels in all coil channels. After phase correction, images from different channel can be combined using weighted summation based, at least in part, on their magnitude.

Due to field inhomogeneity, the positions of water peak varied for the different voxels on the image. At 1030, the peaks are shifted to align together for later processing. At 1040, the magnitude and phase of the signal profile without the metabolite signal were fitted as the baseline using polynomial fitting after the phase adjustment. The baseline correction is performed by subtracting the fitted baseline from the signal profile. At 1050, the spectrum is converted to desired unit, such as parts per million (PPM). Specifically, the profile is then subtracted the fitted baseline to get the spectrum in unit Hz. This spectrum is then converted to the final spectrum in PPM.

At 1060 the spectrums is subjected to a fitting analysis. To fit the spectrum, the spectrum is fitted using three Lorentzian functions. With the fitted spectrum, the different parameters (e.g. amplitude and position) related to each peak can be extracted for further processing. At 1070, the values associated with the voxels are normalized. After the quantification for each voxel, at 1080, parametric maps are generated. The parametric maps are registered and overlaid on a high resolution T2w image.

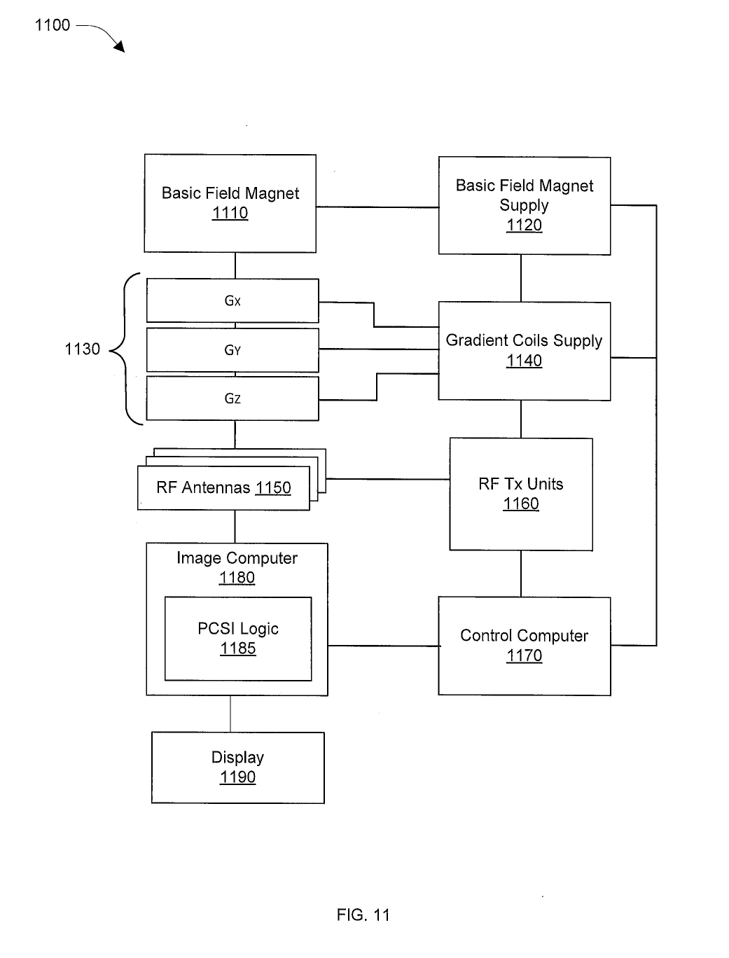

FIG. 11 illustrates an example MR system configured to perform phase cycled magnetic resonance spectroscopic imaging. The apparatus 1100 includes a basic field magnet(s) 1110 and a basic field magnet supply 1120. In practice, the B₀ field may not be uniform, and may vary over an object being imaged by the MRI apparatus 1100. MRI apparatus 1100 may include gradient coils 1130 configured to emit gradient magnetic fields like G_{S}, G_{P} and G_{R}. The gradient coils 1130 may be controlled, at least in part, by a gradient coils supply 1140.

MRI apparatus 1100 may also include an RF antenna 1150 that is configured to generate RF pulses and to receive resulting magnetic resonance signals from an object to which the RF pulses are directed. In some examples, how the pulses are generated and how the resulting MR signals are received may be controlled and thus may be selectively adapted during an MRI procedure. In one example, separate RF transmission and reception coils can be employed. The RF antenna 1150 may be controlled, at least in part, by an RF transmission-reception unit 1160. The gradient coils supply 1140 and the RF transmission-reception unit 1160 may be controlled, at least in part, by a control computer 1170.

The magnetic resonance signals received from the RF antenna 1150 can be employed to generate an image, and thus may be subject to a transformation process such as a two dimensional FFT that generates pixilated image data. The transformation can be performed by an image computer 1180 or other similar processing device. The image computer 1180 includes a PCSI logic 1185 configured to perform the methods described herein with respect to FIG. 1 and FIG. 10. A resulting image data may then be shown on a display 1190. While an MR apparatus 1100 is illustrated, it is to be appreciated that in some examples of the PCSI may be employed with other imaging apparatus and/or methods.

While FIG. 1100 illustrates an example MRI apparatus 1100 that includes various components connected in various ways, it is to be appreciated that other MRI apparatus may include other components connected in other ways. The PCSI logic 1185 may be configured with elements of example apparatus described to perform example method described herein. In different examples, PCSI logic 1185 may be permanently and/or removably attached to an MRI apparatus. While the PCSI logic 1185 is illustrated as a single logic connected to the image computer 1180, it is to be appreciated that the PCSI logic 1185 may be distributed between and/or operably connected to other elements of apparatus 1100. The PCSI logic 1185 may execute portions of the methods described herein.

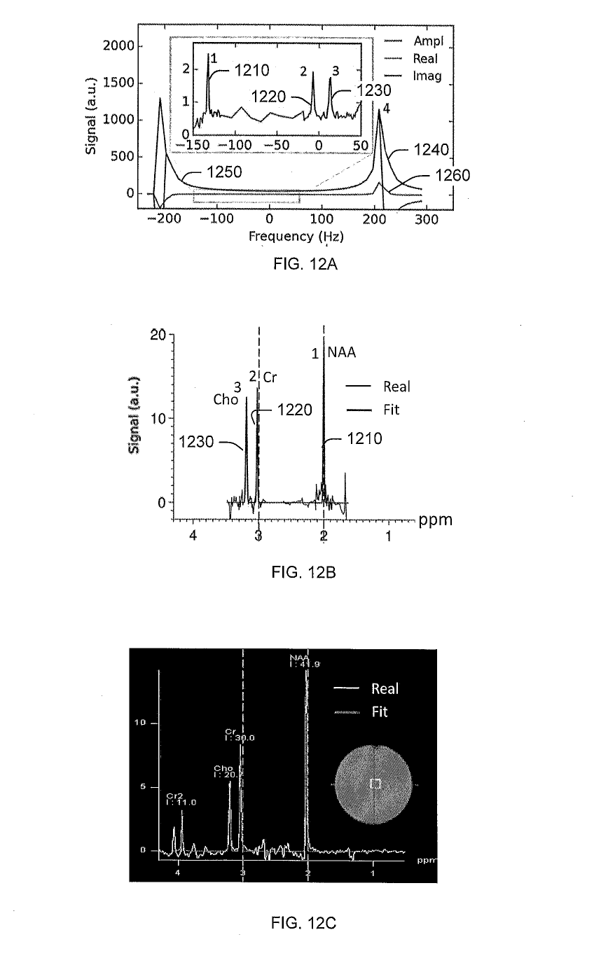

FIG. 12A illustrates one example of a spectral signal associated with phase cycled magnetic resonance spectroscopic imaging. FIG. 12A shows the PCSI signal from nine voxels (˜5.3 cm³) of a spectroscopy phantom. The signal shows the two water peaks on both sides due to the periodic response function. The range between two water peaks is exactly one period length. The phase is adjusted to make the real part of the signal close to pure absorption function. After zooming in, the three metabolite peaks can be easily identified, such as the peaks of NAA 1210, Cr 1220, and Cho 1230.

FIG. 12B illustrates the example of the spectrum associated with phase cycled magnetic resonance spectroscopic imaging in parts per million (ppm). The spectrum in ppm calculated from the spectral signal and includes peaks of NAA 1210, Cr 1220, and Cho 1230, respectively. Amplitude component 1240, real component 1250 represents real part of signal, and imaginary component 1260 represents imaginary part of signal. This metabolite signal can be converted to a spectrum in FIG. 12B after post-processing such as baseline correction and Lorentzian peak fitting. In comparison, a spectrum from a single voxel (8 cm³) using the conventional SVS sequence is shown in FIG. 12C.

FIG. 12C illustrates the example of the spectral signal associated with phase cycled magnetic resonance spectroscopic imaging from a single voxel spectroscopy sequence. The voxel size is 20×20×20 mm³, shown on inset. Two spectra in FIGS. 12B and 12C are aligned for easy comparison. The positions of three peaks are consistent, but the relative heights are different between two spectra.

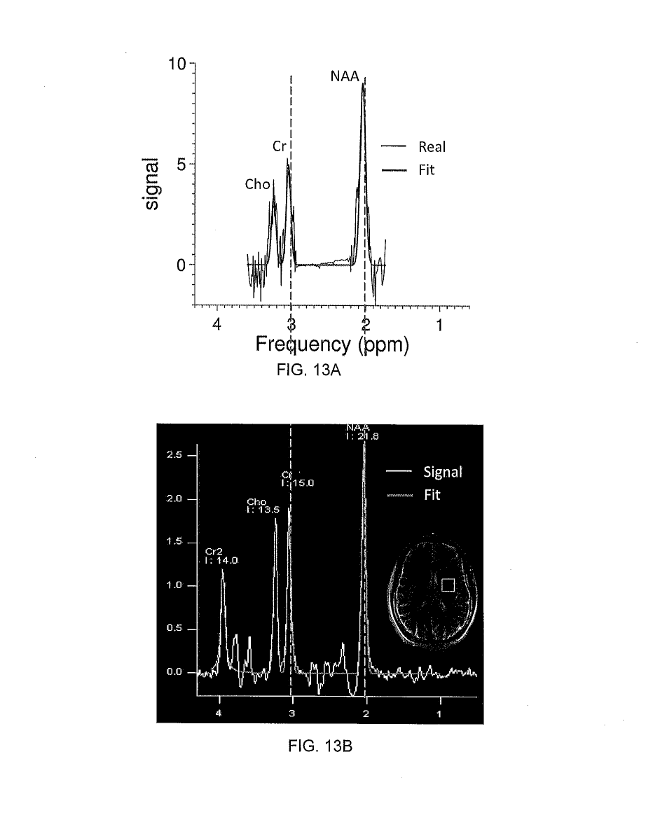

FIG. 13A illustrates one embodiment of the spectrum from healthy volunteer associated with phase cycled magnetic resonance spectroscopic imaging. FIG. 13A shows the PCSI spectrum from a ROI including 9 voxels (18.75×18.75×15 mm³, total 5.3 cm³), in which three metabolite peaks can be easily identified and fitted.

FIG. 13B illustrates the corresponding spectrum using SVS sequence with the voxel size of 20×20×20 mm³, in which the inset demonstrates the location of ROI for both FIGS. 13A and 13B. Both spectra are aligned completely for comparison.

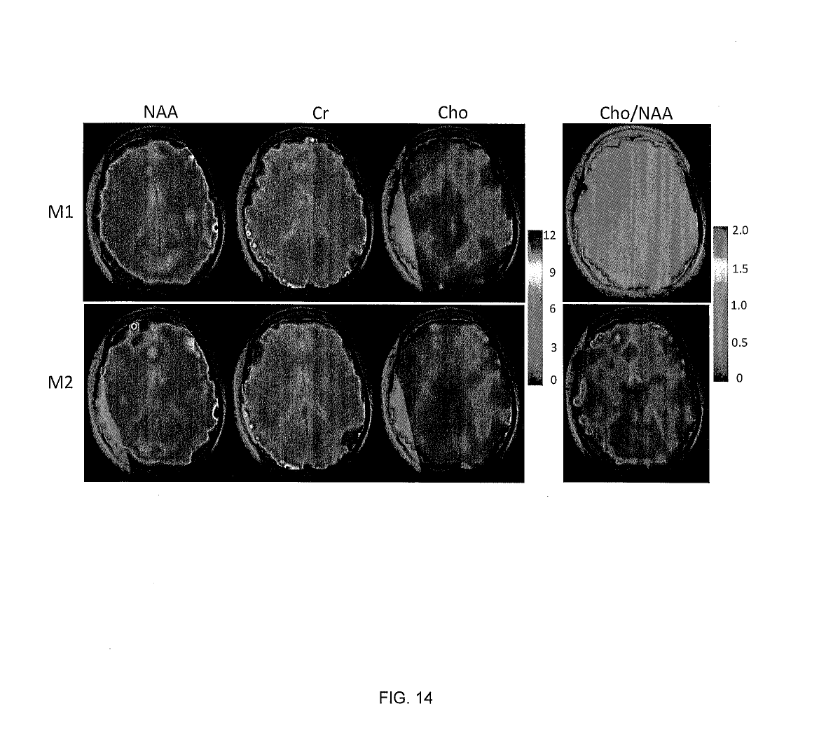

FIG. 14 illustrates one embodiment of parametric maps of three metabolites (NAA, Cr, and Cho) from two repeated measurements using nuPCSI. The parametric maps of the heights of three metabolite peaks are generated in two repeated measures. The spectrum is computed for each voxel by averaging the voxel and its eight neighbors to improve its SNR. The two sets of maps are interpolated and overlaid on the same high resolution T2w image for comparison. The PCSI method demonstrates a good robustness for two separate measurements. Accordingly, the magnitude and location of metabolites can be easily assessed.

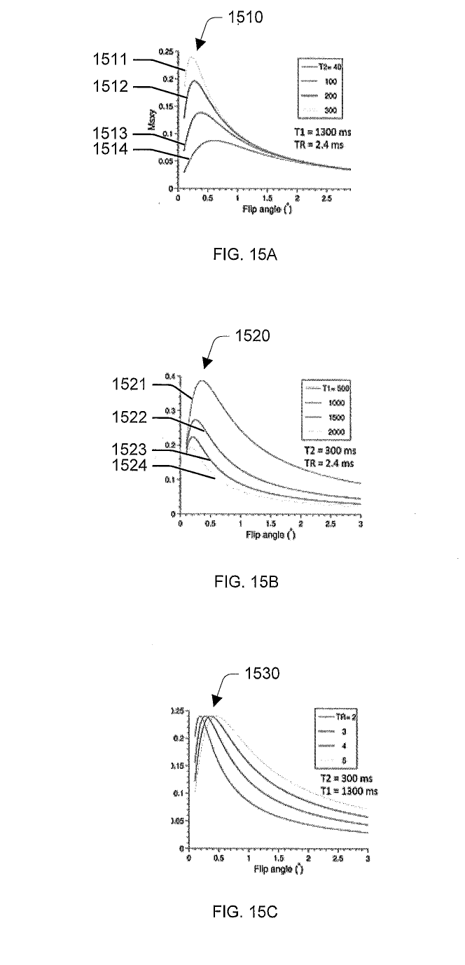

FIGS. 15A, 15B, and 15C illustrate example of simulated PCSI signals. In one embodiment, the relationship between signal and flip angle is studied using simuations. Simulations were performed to investigate the relationship between the signal and flip angles in three cases. First, flip angle and T2 are varied with T1 and TR fixed; second, flip angle and T1 are varied with T2 and TR fixed; third, flip angle and TR are varied with T2 and T1 fixed.

As shown in FIGS. 15A, 15B, and 15C, the flip angle parameter is variable and can change the signal substantially around the desired flip angle. In the cases illustrated, the desired flip angle corresponds to maximum signal at the signal peak 1510 and the signal drops off as the flip angle deviates from the desired flip angle. For example, in FIG. 15A, four T2 values 1511, 1512, 1513, and 1514 are shown while T1 and TR are kept constant. The larger the T2 value is, the higher the signal. For example, T2 value 1514 corresponds to a T2 value of 40 ms while T2 value 1511 corresponds to a T2 value of 300 ms and the T2 value 1511 has a signal with a higher magnetization than that of T2 value 1514.

In FIG. 15B, four T1 values 1521, 1522, 1523, and 1524 are shown while T2 and TR are kept constant. As with FIG. 15A, a desired flip angle corresponds to maximum signal at the signal peak 1520 and the signal drops off as the flip angle deviates from the desired flip angle. The smaller the T1 value is, the higher the signal. For example, T1 value 1524 corresponds to a T1 value of 2,000 ms while T1 value 1521 corresponds to a T1 value of 500 ms, and the T1 value 1521 has a signal with a higher magnetization than that of T1 value 1521.

In FIG. 15C, T1 and T2 parameters are kept constant but TR is varied. While varying the TR does not affect the amplitude of the signal, the peaks 1530 are shifted as the flip angle changes.

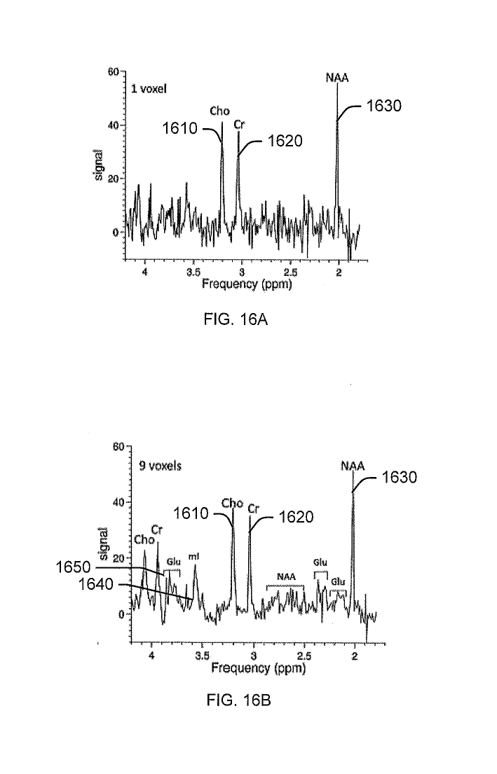

FIG. 16A illustrates one embodiment of a PCSI spectrum of one voxel from high-resolution data showing peaks corresponding to example metabolites. As discussed above, the PCSI may be used to identify substances, such as metabolites. One category of metabolite may be J-coupled metabolites. For J-coupled metabolites, signals may be smaller. Therefore, to identify J-coupled metabolites, a higher SNR signal is needed. PCSI can provide enough SNR to see those J-coupled metabolites.

Phantom spectra from PSCI data having a 64×32 acquisition matrix and a higher in-plane resolution, (e.g., 3.75×3.75), may be used. FIG. 16A illustrates one embodiment of a PCSI spectrum of one voxel of the data acquisition showing peaks corresponding to metabolites having larger signals such as Cho 1610, Cr 1620, and NAA 1630 are shown. FIG. 16B illustrates one embodiment of a PCSI spectrum of nine voxels of the data acquisition showing peaks corresponding to example J-coupled metabolites myo-inositol (ml) 1640 and glutamate (Glu) 1650, which can be visualized in averaged spectrum from the nine voxels.

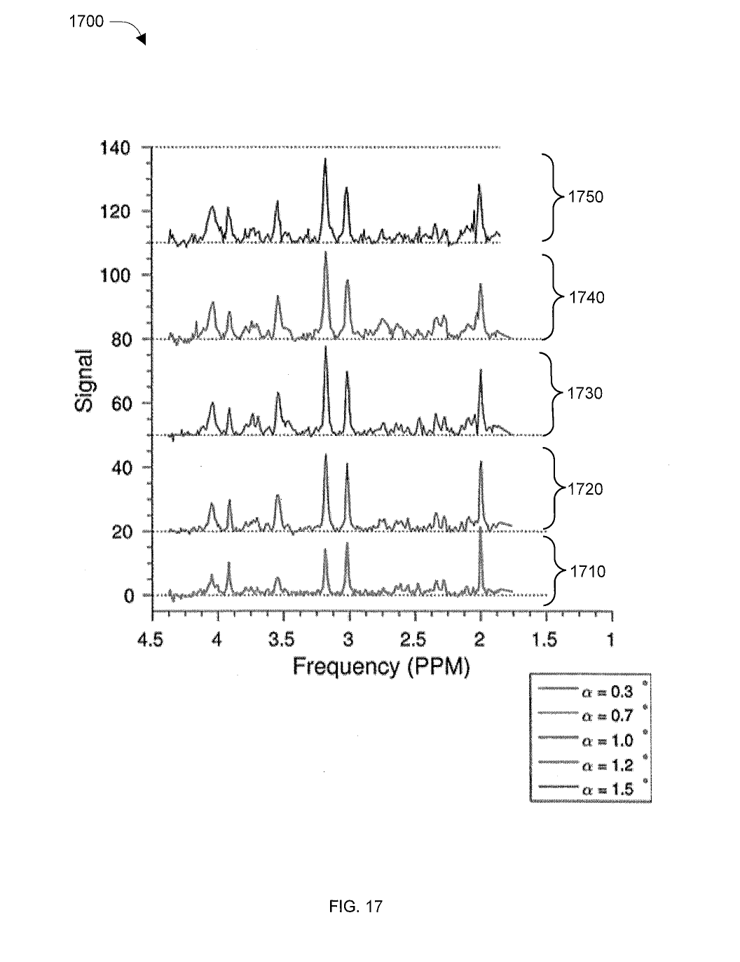

FIG. 17 illustrate example PCSI spectrum corresponding to different flip angles. FIG. 17 shows a series of PCSI spectra with different flip angles from a phantom. For example, spectra 1710 corresponds to a flip angle, α, 0.3°, 1720 corresponds to a flip angle, α, 0.7°, 1730 corresponds to a flip angle, α, 1.0°, 1740 corresponds to a flip angle, α, 1.2°, and 1750 corresponds to a flip angle, α, 1.5°.

Most of signals increase as the flip angle, α, increases when flip angle, α, is less than 1°. Then the signals start to decrease when flip angle, α, increases further to 1.5°. Accordingly, the maximum PCSI signal occurs at a flip angle, α, of around 1° in this example phantom study. Thus, a optimal prescribed flip angle can be determined based, at least in part, on such experiments.

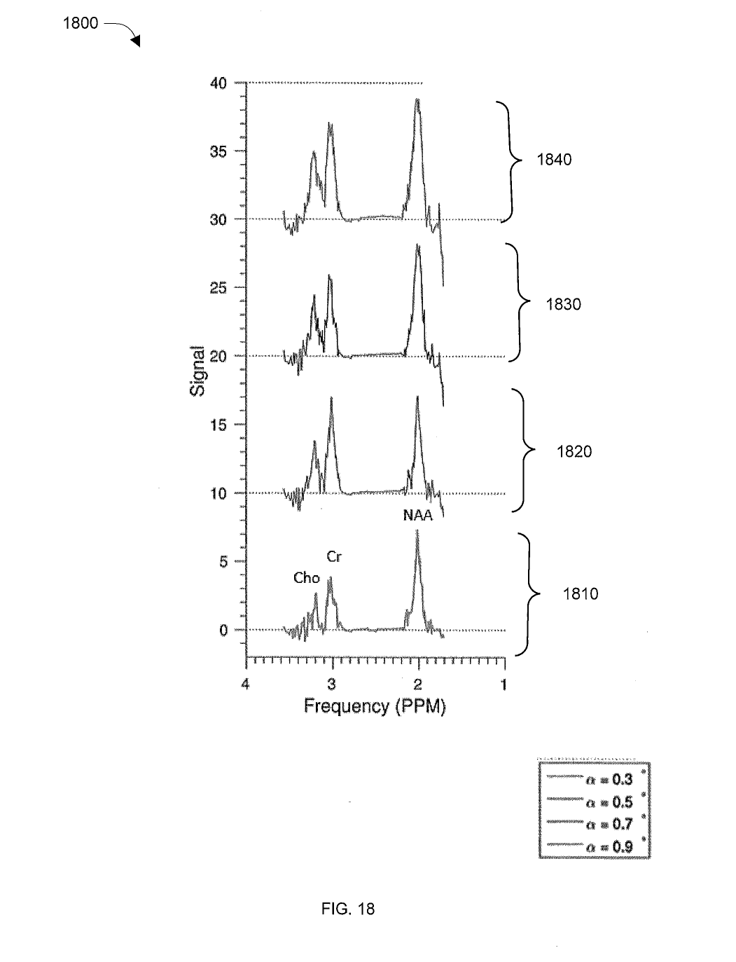

FIG. 18 illustrate example fitted PCSI spectrum corresponding to different flip angles. FIG. 18 shows a series of the fitted PCSI spectra 1810, 1820, 1830, 1840, and 1850 with three metabolites from a healthy volunteer. All metabolite signals increases as flip angle, α, increases. The signals of Cr and Cho approximately doubled from flip angle, α, =0.3° to flip angle, α, =0.9°.

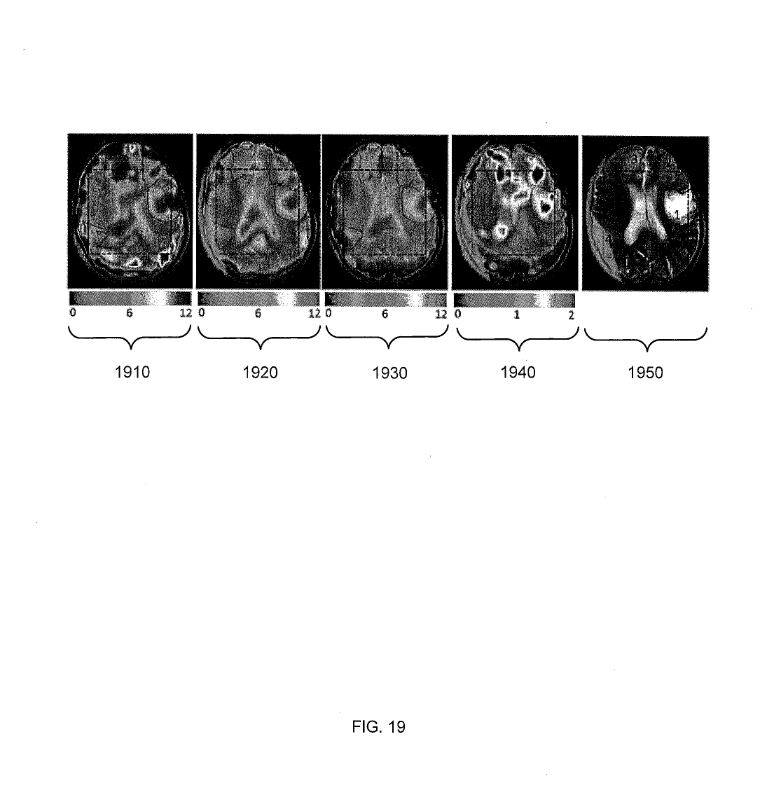

FIG. 19 illustrate example metabolic parameter maps having regions of identified lesions. The parametric maps 1910, 1920, 1930, 1940, and 1950 illustrate examples of parametric maps showing metabolites including Cho, Cr, and NAA and the Cho/NAA ratios.

The PCSI provides opportunities to make MRSI faster and easier for possible regular clinical applications. Without water and fat suppression in PCSI, MRI technicians don't need to spend a lot of time to place a large number of outer volume suppression (OVS) slices when balancing coverage of peripheral regions and loss of cortical signal. The precise manual placements of OVS slices are highly operator-dependent and hard to be repeated even for the same operator, which generate inter-subject variability to select the volume of interest (VOI). PCSI does not require OVS so as to avoid the above issues, reduce subjective variability, and greatly simplify the scanning procedures. The conventional MRSI typically has unreliable spectra at the edges of brain due to OVS of skull signal and limited coverage of the PRESS excitation. PCSI is less susceptible to such issues due to its simple implementation without OVS.

Human PCSI spectrum shows larger peak widths, which could be due to different shimming. The full width at half maximum (FWHM) of water peak is about 35.7 Hz for the PCSI method, and is 17.5 Hz for the SVS result in FIG. 13A. In contrast, the widths of peaks using the PCSI method are much smaller in the phantom since its FWHM is 6.5 Hz in FIG. 12. It demonstrates that the better shimming led to the narrower peak. The shimming in the PCSI method is automatically shimming performed by scanner (advanced shim mode for spectroscopy). In human studies, FWHM using this shimming method for a single slice is larger than 30 Hz. However, several advanced shimming techniques including higher order shimming are reported to achieve much better shimming such as 15 Hz or below.

The PCSI method utilizes an ultra-low flip angle and had much lower (hundreds of times lower) specific absorption rate (SAR) in comparison with other conventional spectroscopy sequences. This makes PCSI a much safer technique for spectroscopic imaging. The PCSI method did not require water and fat suppression to get rid of water and fat signal and improve SNR because metabolite signals in the PCSI are intrinsically unsusceptible to water and fat signal. Therefore, there is no need to place many OVS slices for spatial suppression and apply CHESS pulse for water suppression. This feature had further greatly reduced SAR in the PCSI sequence. In addition, this feature made PCSI a much simpler technique for MR technician to scan automatically like a regular clinical imaging sequence.

Furthermore, PCSI methods described herein provide a possibility to speed up acquisition in frequency dimension by under-sampling spectra in certain ranges of frequency. In this study, there are two ranges with higher sampling density, which included targeted metabolite peaks, and the other ranges are under-sampled. By using this scheme, total acquisition time is 2.5 times faster in comparison with that if the full spectrum are acquired with high sampling density. This acquisition scheme could be further refined to speed up based, at least in part, on accurate prior knowledge of metabolite location. In addition, we can further speed up PCSI using parallel imaging or compressed sensing techniques in future.

The PCSI method has great potentials for different applications. First, the 2D PCSI method may be implemented on 3D imaging, which could have higher SNR and efficiency since each 3D measurement requires only one steady state like 2D. In addition, PCSI may be utilized in multinuclear spectral imaging, such as fluorine and sodium imaging. Time-resolved spectroscopy has clear advantage for single voxel; the PCSI method is advantageous when doing 2D or 3D spectroscopic imaging, especially for higher resolution. Acquisition matrices 32×32 and 64×64 may be used. With certain configuration and good shimming, a high resolution spectroscopic image with a matrix 128×128 or 256×256 is possible when high order shimming, high-temperature superconductor coil and parallel transmit techniques are used with this PCSI technique in future.

### Definitions

The following includes definitions of selected terms employed herein. The definitions include various examples and/or forms of components that fall within the scope of a term and that may be used for implementation. The examples are not intended to be limiting. Both singular and plural forms of terms may be within the definitions.

References to “one embodiment”, “an embodiment”, “one example”, “an example”, and so on, indicate that the embodiment(s) or example(s) so described may include a particular feature, structure, characteristic, property, element, or limitation, but that not every embodiment or example necessarily includes that particular feature, structure, characteristic, property, element or limitation. Furthermore, repeated use of the phrase “in one embodiment” does not necessarily refer to the same embodiment, though it may.

“Computer storage medium”, as used herein, is a non-transitory medium that stores instructions and/or data. A computer storage medium may take forms, including, but not limited to, non-volatile media, and volatile media. Non-volatile media may include, for example, optical disks, magnetic disks, and so on. Volatile media may include, for example, semiconductor memories, dynamic memory, and so on. Common forms of a computer storage medium may include, but are not limited to, a computer-readable medium, a floppy disk, a flexible disk, a hard disk, a magnetic tape, other magnetic medium, an ASIC, a CD, other optical medium, a RAM, a ROM, a memory chip or card, a memory stick, and other media that can store instructions and/or data.

“Logic”, as used herein, includes a computer or electrical hardware component(s), firmware, a non-transitory computer storage medium that stores instructions, and/or combinations of these components configured to perform a function(s) or an action(s), and/or to cause a function or action from another logic, method, and/or system. Logic may include a microprocessor controlled by an algorithm to perform one or more of the disclosed functions/methods, a discrete logic (e.g., ASIC), an analog circuit, a digital circuit, a programmed logic device, a memory device containing instructions, and so on. Logic may include one or more gates, combinations of gates, or other circuit components. Where multiple logics are described, it may be possible to incorporate the multiple logics into one physical logic component. Similarly, where a single logic component is described, it may be possible to distribute that single logic component between multiple physical logic components. In some embodiments, one or more of the components and functions described herein are implemented using one or more of the logic components.

“Signal”, as used herein, includes but is not limited to, electrical signals, optical signals, analog signals, digital signals, data, computer instructions, processor instructions, messages, a bit, a bit stream, or other means that can be received, transmitted and/or detected.

“User”, as used herein, includes but is not limited to, one or more persons, technicians, software, computers or other devices, or combinations of these.

Some portions of the detailed descriptions that follow are presented in terms of algorithms and symbolic representations of operations on data bits within a memory. These algorithmic descriptions and representations are used by those skilled in the art to convey the substance of their work to others. An algorithm, here and generally, is conceived to be a sequence of operations that produce a result. The operations may include physical manipulations of physical quantities. Usually, though not necessarily, the physical quantities take the form of electrical or magnetic signals capable of being stored, transferred, combined, compared, and otherwise manipulated in a logic, and so on. The physical manipulations create a concrete, tangible, useful, real-world result.

It has proven convenient at times, principally for reasons of common usage, to refer to these signals as bits, values, elements, symbols, characters, terms, numbers, and so on. It should be borne in mind, however, that these and similar terms are to be associated with the appropriate physical quantities and are merely convenient labels applied to these quantities. Unless specifically stated otherwise, it is appreciated that throughout the description, terms including processing, computing, determining, and so on, refer to actions and processes of a computer system, logic, processor, or similar electronic device that manipulates and transforms data represented as physical (electronic) quantities.

Example methods may be better appreciated with reference to flow diagrams. While for purposes of simplicity of explanation, the illustrated methodologies are shown and described as a series of blocks, it is to be appreciated that the methodologies are not limited by the order of the blocks, as some blocks can occur in different orders and/or concurrently with other blocks from that shown and described. Moreover, less than all the illustrated blocks may be required to implement an example methodology. Blocks may be combined or separated into multiple components. Furthermore, additional and/or alternative methodologies can employ additional, not illustrated blocks.

While for purposes of simplicity of explanation, illustrated methodologies are shown and described as a series of blocks. The methodologies are not limited by the order of the blocks as some blocks can occur in different orders and/or concurrently with other blocks from that shown and described. Moreover, less than all the illustrated blocks may be used to implement an example methodology. Blocks may be combined or separated into multiple components. Furthermore, additional and/or alternative methodologies can employ additional, not illustrated blocks.

To the extent that the term “includes” or “including” is employed in the detailed description or the claims, it is intended to be inclusive in a manner similar to the term “comprising” as that term is interpreted when employed as a transitional word in a claim.

While example systems, methods, and so on have been illustrated by describing examples, and while the examples have been described in considerable detail, it is not the intention of the applicants to restrict or in any way limit the scope of the appended claims to such detail. It is, of course, not possible to describe every conceivable combination of components or methodologies for purposes of describing the systems, methods, and so on described herein. Therefore, the disclosure is not limited to the specific details, the representative apparatus, and illustrative examples shown and described. Thus, this application is intended to embrace alterations, modifications, and variations that fall within the scope of the appended claims, which satisfy the statutory subject matter requirements of 35 U.S.C. § 101.

As used in this application, “or” is intended to mean an inclusive “or” rather than an exclusive “or”. Further, an inclusive “or” may include any combination thereof (e.g., A, B, or any combination thereof). In addition, “a” and “an” as used in this application are generally construed to mean “one or more” unless specified otherwise or clear from context to be directed to a singular form. Additionally, at least one of A and B and/or the like generally means A or B or both A and B. Further, to the extent that “includes”, “having”, “has”, “with”, or variants thereof are used in either the detailed description or the claims, such terms are intended to be inclusive in a manner similar to the term “comprising”.

Further, unless specified otherwise, “first”, “second”, or the like are not intended to imply a temporal aspect, a spatial aspect, an ordering, etc. Rather, such terms are merely used as identifiers, names, etc. for features, elements, items, etc. For example, a first channel and a second channel generally correspond to channel A and channel B or two different or two identical channels or the same channel.

Although the disclosure has been shown and described with respect to one or more implementations, equivalent alterations and modifications will occur based, at least in part, on a reading and understanding of this specification and the annexed drawings. The disclosure includes all such modifications and alterations and is limited only by the scope of the following claims.

What is claimed is:

1. A method for acquiring magnetic resonance data from a sample, comprising:
applying an excitation radio frequency (RF) pulse having a low flip angle to a sample;
adjusting phase of the RF to sweep through a frequency range based, at least in part, on phase cycled spectroscopic imaging (PCSI),
sampling in the frequency range; and
receiving a set of data based, at least in part, on the sampling in the frequency range.

2. The method for acquiring magnetic resonance data from the sample of claim 1, wherein the low flip angle is an ultra-low flip angle of less than one degree.

3. The method for acquiring magnetic resonance data from the sample of claim 1, wherein the PCSI is based, at least in part, on a balanced steady state free procession sequence.

4. The method for acquiring magnetic resonance data from the sample of claim 1, wherein data is acquired in a k- and frequency space.

5. The method for acquiring magnetic resonance data from the sample of claim 1, wherein adjusting the phase of the RF includes cycling the phase at a specified sweep rate.

6. The method for acquiring magnetic resonance data from the sample of claim 1, wherein the sampling in the frequency range is at non-continuous frequencies.

7. The method for acquiring magnetic resonance data from the sample of claim 1, further comprising selecting target frequencies in the frequency range based, at least in part, on a target metabolite; and wherein the sampling is performed at the target frequencies.

8. A method, comprising:
reconstructing an image having a plurality of voxels associated with a received image spectra;
phase correcting the image spectra;
shifting peaks in the image spectra to align the peaks;
performing a phase adjustment to fit a baseline and perform a baseline correction;
converting the image spectra to a desired unit;
fitting the spectra using Lorentzian functions;
normalizing the spectra; and
generating parametric maps.

9. The method of claim 8, where the phase correcting is based, at least in part, on a water peak.

10. The method of claim 8, wherein the phase correcting makes all phases consistent for each voxels in coil channel.

11. The method of claim 8, wherein the desired unit is parts per million.

12. The method of claim 8, further comprising performing a baseline correction including a fitted baseline being subtracted from a profile associated with the spectra.

13. The method of claim 12, wherein the baseline correction is performed using polynomial fitting.

14. A magnetic resonance apparatus, comprising
applying an excitation radio frequency (RF) pulse having a low flip angle to a sample;
adjusting phase of the RF to sweep through a frequency range based, at least in part, on phase cycled spectroscopic imaging (PCSI); and
receiving a set of data based, at least in part, on the sampling in the frequency range.

15. The magnetic resonance apparatus of claim 14, wherein the low flip angle is an ultra-low flip angle of less than one degree.

16. The magnetic resonance apparatus of claim 14, wherein the PCSI is based, at least in part, on a balanced steady state free procession sequence.

17. The magnetic resonance apparatus of claim 14, wherein data is acquired in a k- and frequency space.

18. The magnetic resonance apparatus of claim 14, wherein adjusting the phase includes cycling the RF phase at a specified sweep rate.

19. The magnetic resonance apparatus of claim 14, further comprising selecting target frequencies in the frequency range based, at least in part, on a target metabolite; and wherein the sampling is performed at the target frequencies.

20. The magnetic resonance apparatus of claim 19, wherein the example metabolites include at least one J-coupled metabolite.
